(19) United States
(12) Patent Application Publication
(10) Pub. No.: US 2016/0009560 A1
(43) Pub. Date: Jan. 14, 2016

(54) EPITAXIAL GRAPHENE WITH THICKNESS MODULATION

(71) Applicant: SABANCI ÜNIVERSITESI, Tuzla, Istanbul (TR)

(72) Inventors: Ismet Inönü KAYA, Tuzla, Istanbul (TR); Cenk YANIK, Tuzla, Istanbul (TR)

(73) Assignee: SABANCI ÜNIVERSITESI, Tusla, Istanbul (TR)

(21) Appl. No.: 14/765,439

(22) PCT Filed: Feb. 4, 2013
(86) PCT No.: PCT/EP2013/052162

§ 371 Date: Aug. 3, 2015

(51) Int. Cl. C01B 31/04; C30B 1/02; C30B 1/10

(52) U.S. Cl. CPC C01B 31/0461; C30B 1/10; C30B 1/02; C01B 2204/04

(57) ABSTRACT

The present invention relates to a novel graphene sheet with modulated thickness comprising electrically conductive areas of an array of ridges constituting a grid structure on graphene surface wherein the ridging areas are integrally formed with the graphene sheet and are themselves made of graphene. The invention further relates to a method for producing the thickness modulated graphene material of above type by way of a special capping technique where the capping structure having an array of protrusions is involved so that the said capping would transfer its physical structure to the graphene surface to form areas with improved electrically conductivity and optical transparency.

### TECHNICAL FIELD OF THE INVENTION

The present invention relates to in situ grown graphene sheets with thickness modulation, which themselves constitute a single or multiple layers of graphene arbitrarily or regularly patterned by a given template. The invention further relates to a novel method for producing graphene sheets with grid structures in situ by way of a specially designed epitaxial growth process that is carried out in a confined and controlled atmosphere.

### BACKGROUND/SUMMARY OF THE INVENTION

Graphene is a single layer of carbon atoms arranged in a honeycomb crystal in two dimensional structures. The realization of graphene has stimulated a large amount of experimental and theoretical research due to its extraordinary electronic and mechanical properties such as high conductance, mobility, mechanical strength, optical transparency, long spin coherence length etc. Based on these properties, graphene exhibits a very promising potential for a wide variety of new technological applications such as displays, touch screens, electrodes, performance batteries, supercapacitors, wide-band photo detectors, DNA separation and hydrogen storage. Among these, graphene has particular advantages in production of OLED/PLED/LCD displays because of its advantageous features in terms of conductivity and optical transparency. The conventional display technologies employ Indium Tin Oxide (ITO) as the electrode material which, however, is rapidly getting more expensive as the rare indium element is expected to become scarce in the near future. In addition, ITO is not flexible enough to meet the requirements of the future flexible display technologies. Graphene seems to be a promising candidate to replace the conventional ITO. A single layer graphene absorbs only 2.3% of visible light such that it has 97.7% transmittance, whereas double layer graphene has 95.4% transmittance. However, at the moment conductance of graphene at the required transmittance needs improvement to catch ITO.

Graphene has also great potential for electronic applications due to its high mobility, high conductivity and electrically adjustable carrier density. Monolayer graphene has zero band gap with linear energy momentum dispersion. Energy gap can be opened in graphene by constricting it with about <100 nm. Bilayer graphene has zero band gap with quadratic dispersion and its gap can be adjusted by electric field. The electrical noise in graphene is known to be very low. Therefore, monolayer and bilayer graphene can have wide range of electronics applications including high frequency transistors.

It is however known that monolayer/bilayer/trilayer graphene has different band gap structures with different functioning in electronic devices such that conductivity of graphene increases with number of layers whereas optical transmission decreases with an inverse proportion. Therefore, it is the challenge for the skilled artisans in the field to obtain graphene sheets with minimum of graphene layers while ensuring maximum electronic conductivity. Thus, it becomes an important issue to optimize the thickness of graphene sheets in order to ensure better conductivity with minimum loss in transparency.

To solve the problems hereinabove, WO 2011/112589 discloses different electrode materials made of graphene which is supported with a grid like structure generally made of metals in order to further improve the electrical conductivity. In alternative embodiments, the grid structure is specified as being selected from metals, carbon nanotubes, graphite, amorphous carbons, metal particles, metal nanoparticles, metal microparticles and combinations thereof. A process involving a plurality of steps including, positioning of a grid structure on a top surface of the substrate and placing a graphene layer on a top surface of said grid structure followed by associating the graphene with said grid structure is disclosed. Apparently the proposed product, especially the grid materials such as metals and carbonaceous materials have certain drawbacks as having a very low optical transparency while the process for producing the same is costly and cumbersome to practice in the real life.

There are various techniques described in the state of the art for production of graphene such as mechanical exfoliation from graphite, epitaxial growth on SiC, chemical vapor deposition, reduction from graphene oxide. In more detail, large scale graphene can be produced by chemically exfoliating from graphite, by chemical vapor deposition on various metal surfaces such as copper and nickel, and by epitaxially growing on Si or C surface of silicon carbide (SiC). The growth of epitaxial graphene on the Si or C surfaces of SiC is considered to be one of the most promising techniques for obtaining high quality large scale graphene for electronic applications. On Si side, graphene grows slowly and in a self-limited manner to produce a monolayer. However, the interface layer between SiC and graphene adversely affects the mobility of graphene grown on Si surface of SiC. Graphene grown on the C-face has high mobility. However, its growth under vacuum is fast and not self-limited, and produces high concentration of crystalline defects. Therefore, a precise control over the Si evaporation rate is required.

US 2011/0223094-A1 addresses the aforesaid issues and prominently proposes a method based on epitaxial growth of graphene from SiC substrates in vacuum environment, where SiC and a Si source are kept in close proximity in an opposing manner at about 25 microns so that sublimation of Si and formation of graphene layer may easily be controlled. It is reported that an annealing temperature higher than 1530° C. results in the formation of very high quality, micrometer scale graphene sheets. It is further noted that two sides of the SiC wafers, namely “Si-terminated” and “C-terminated” sides, are different because sublimation rate of Si from the Si-terminated surface is slower than C-terminated surface of the SiC crystal as compared in the same temperature. Therefore, it is found rather preferable to use the Si-terminated surface for the sake of easier control of graphene.

The inventors of the present invention have very recently reported that growth rate of graphene may successfully be controlled even if growing is carried out on C-face of SiC by way of a special capping technique, where SiC and the cap are brought into close proximity as low as 300 nm and sublimated atoms are confined in a half open cavity in order to establish a vapor equilibrium between the two stacks (C. Celebi, C. Yanik, A. G. Demirkol, I. I. Kaya, “The effect of a SiC cap on the growth of epitaxial graphene on SiC in ultra-high vacuum”, Carbon 50 (2012) 8). The inventors further noted that the success of the present technique lies in the fact that small volume cavity in between the two stacks prevents sublimated Si atoms to escape freely into vacuum environment and maintains a relatively high Si partial pressure near the sample surface which forces most of the constituent with Si atoms to condense on the SiC surface, and hence leads to an extremely low growth rate of graphene compared to bare UHV sublimation process. This method is surely a considerable progress as it eliminates the drawbacks associated with C-face of SiC as stated in US 2011/0223094-A1, and therefore enables growing of graphene sheets with higher mobility and sufficiently uniform topographic surface.

To this end, monolayer and multilayer graphene with improved mobility and uniformity is obtainable by the state of the art techniques. However, the state of the art techniques do not allow surface modulation of graphene sheets without excessive and exhaustive steps, and yet the need exists for straightforward methods that eliminate costly and cumbersome applications of prior art. Moreover, it is very hard according to the conventional techniques to obtain graphene sheets having local areas with improved electrical conductivity. The present invention solves the foregoing problems by providing a novel graphene structure containing a graphene sheet with surface modulation to obtain a modulated thickness varying regularly or irregularly along said surface of the graphene, also with a novel method enabling production of the foregoing graphene structure in situ. In a best mode of carrying out the present invention the graphene structure comprises an array of graphene ridges formed integrally thereon in order to form a grid structure, thereby to obtaining the maximum electrical conductivity and optical transitivity. The invention provides also solution to the drawbacks of conventional processes by a novel straightforward method involving a capping structure in the form of a complementary template to the grid structure of the graphene sheet such that said graphene sheet with local ridges is formed in situ during Si sublimation in a confined volume.

### SUMMARY OF THE INVENTION

The present invention aims at providing a novel graphene material and a simplified process for producing the same in order to eliminate the problems of prior art.

Hence, according to a first aspect, is provided a graphene sheet with modulated surface, preferably in the form of an array of ridges constituting a grid structure on graphene surface wherein the ridging areas are integrally formed with the graphene sheet and are themselves made of graphene. This structure is particularly advantageous with its one piece arrangement with the ridging areas made of optically transparent graphene as the prior art arrangements require separate materials which are fairly transparent. Therefore, the novel material of the present invention is very promising for visual display applications.

According to a second aspect, the invention pertains to a straightforward and cost effective method for producing the graphene sheets of above type, comprising providing a silicon carbide primary substrate, providing a capping substrate having a modulated surface, said material having a modulated topography, preferably in the form of an array of protrusions, positioning said capping substrate on a top surface of the primary substrate and providing a spacing therebetween to form a cavity with a modulated gap, preferably reducing the pressure in said cavity to vacuum, heating the substrates to a temperature sufficient to sublimate silicon from the primary substrate and forming a graphene layer thereon, proceeding with the sublimation step until a graphene sheet with a modulated surface having varying thickness is obtained.

It is known that graphene sheets with higher thickness have better electrical conductivity but lower optical transmittance. Thus, the graphene sheets with varying thickness according to the present invention provide local areas with better electrical conductivity without a substantial effect on optical properties. Such areas are preferably in the form of an array of ridges constituting a grid structure on graphene surface.

In the context of the present invention, the term “modulated surface” refers to a modulation on at least a substantial part of the surface such that the surface has a varying thickness with a regular or irregular pattern. The irregular pattern means a randomly thickening and thinning structure in spatial domain. An irregular pattern may for instance constitute a plurality of regular patterns in smaller scale which however form an irregular pattern in large scale. By analogy, the phrase “modulated gap” or “modulated cavity” in the sense of the present invention refers to a volume having varying height perpendicular to the graphene forming surface.

In the method specified above, the graphene sheet and the grid structure which is formed of graphene based ridging areas are produced integrally in situ without cumbersome extra procedures. According to a preferred embodiment, the capping structure includes protrusions that substantially limit the graphene growth on the corresponding surface of the SiC primary surface, whereas in the areas where no protrusion correspond the SiC surface grows graphene more rapidly such that ridging areas are formed. In this way, a modulated surface of graphene can be obtained on the sensitive sheet material.

### BRIEF DESCRIPTION OF THE FIGURES

FIG. 1 shows a SEM image of the graphene sheet with grid structure according to an embodiment of the present invention wherein the ridging areas are formed with quadrangle shape.

FIG. 2 shows a SEM image of the graphene sheet with grid structure according to another embodiment of the present invention wherein the ridging areas are formed with hexagonal shape.

FIG. 3, is a graphene with grid structure according to prior art.

FIG. 4 is schematic illustration of the Si confinement technique for growing graphene where different orifice heights (d₁, d₂, d₃) are employed in three independent cavities and effect thereof on grow rate of graphene is evaluated.

FIG. 5 is diagram showing the direct correlation between the orifice height and graphene grow rate, which diagram is obtained based on measurements with Raman spectroscopy as shown in the diagram.

FIG. 6 is a schematic illustration of an assembly for carrying out the Si confinement and capping technique.

FIG. 7 shows the assembly of FIG. 6 with various exemplary capping structures as shown with the SEM images of FIGS. 7a, 7b, 7c and 7d.

FIG. 8 shows an intersection of the graphene sheet obtained according to the Example of the present description. FIG. 8a is a diagram of Raman measurement obtained from the region “a” (thick region) on the graphene sheet whereas FIG. 8b shows Raman diagram of the region “b” (thin region) which is a graphene based ridging area.

### DETAILED DESCRIPTION OF THE INVENTION

It is one of the objects of the present invention to provide a new material which is based on monolayer and multilayer graphene wherein the material has in-situ grown laterally modulated thickness to form locally thicker regions thereon possibly in the form of a grid structure.

A further objective is that an epitaxial production of graphene with the said grid structure in a controllable way on Si-terminated (0 0 0 1) or C-terminated (0 0 0 −1) polar face of a SiC crystal is achieved simply by a surface thermal decomposition process.

Referring to the first objective, there is provided a graphene sheet with one or more layers of graphene. The number of base layers can be selected depending on the circumstances of use, such as lower number of layers (i.e. mono- or bi-layer) may be preferable when optical transparency is of particular interest, and multilayers may be preferable if the primary concern is electrical conductivity. One of the advantages of the new material according to the present invention lies in the fact that better electronic conductivity is achieved with minimum number of graphene layers. This is attained by virtue of the locally thicker areas such as ridges integrally formed with the graphene sheet where the surface of said graphene sheet modulates with a regular or irregular pattern. In a preferred embodiment, said ridges are configured as an array such that a grid structure is obtained with better electrical conductivity. As may be appreciated by those skilled in the art, surface modulation of the graphene sheets may be arranged in any desired pattern, i.e. thicker in a particular area and thinner in the rest of the surface topography.

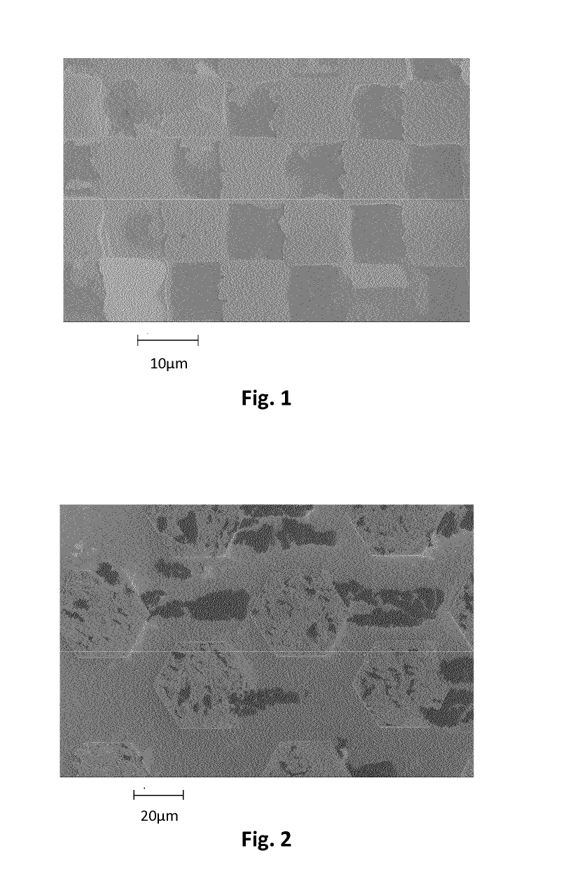

Grid structures formed by quadrangle and hexagonal arrays of ridges according to preferred embodiments of the present invention are shown in FIGS. 1 and 2, although different shapes of ridges forming the grid structure such as triangular, circular, honeycomb or any arbitrary shape can be used. Honeycomb (hexagonal) ridges may be preferred for mechanical endurance. The regular ridges which constitute islands of graphene on a graphene base sheet provide electrically conductive areas without a substantial distortion of optical transparency in the overall sheet material. As noted in the background art, each layer of graphene absorbs 2.3% of visible light; hence the grid structure of the present invention would be very promising to increase electrical conductivity without increasing the number of graphene layers and distorting optical transparency, because the thick regions provide maximum electrical conductivity whereas the thin regions provide maximum optical transparency.

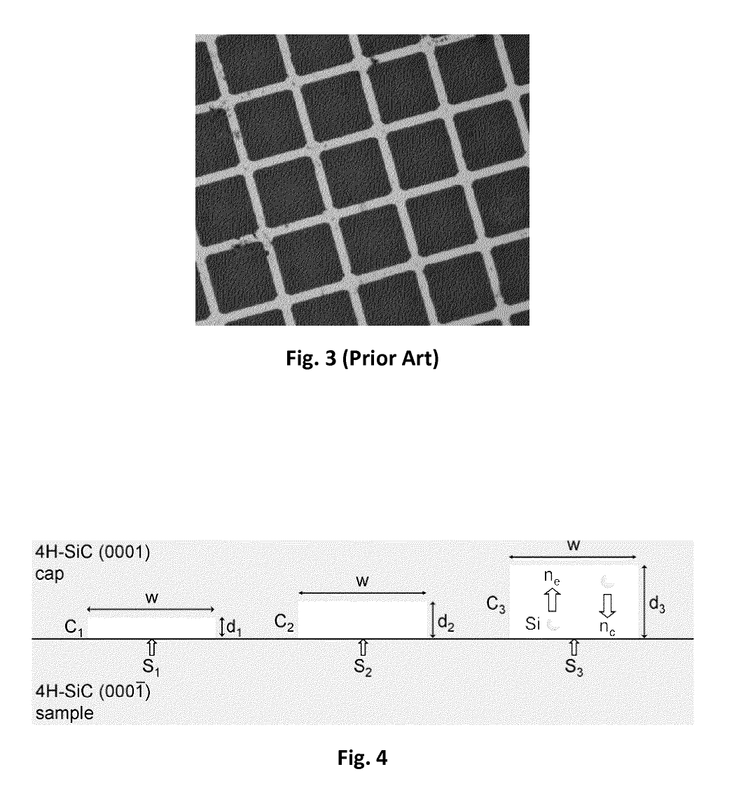

Unlike the advantages set out above, the prior art materials with grid structure as shown in FIG. 3 require a different conductive material that is integrated into graphene with cumbersome processing. Those skilled in the art will readily appreciate that such conductive materials like metals or carbon nanotubes are not only costly and complicated to apply into graphene, but also have the very likely potential to decrease optical transparency rendering them very unfeasible in display technologies.

Referring now to the second object of the present invention, the inventors noted that the novel method of the present invention is not only suitable to grow graphene from Si-face of the SiC substrate, but is also useful to grow graphene from C-face of the SiC substrate in a controlled manner. As noted in the background art, the growth is much faster on the C-face due to high sublimation rate of Si atoms during the high temperature annealing process in vacuum. Hence, for the same growth conditions, multiple layers are more readily formed on the C-face than on the Si-face surface of SiC. Another important aspect is that the elevated Si evaporation rate on C-face SiC leads to the formation of unavoidably high concentration of crystalline defects in the graphene matrix. In order to obtain defect free films with desired thickness uniformity on this particular polar surface, a precise control over the Si evaporation rate is necessarily required. A variety of different approaches, based on the confinement controlled sublimation of Si, are employed to reduce the uncontrollable growth rate of epitaxial graphene on the C-face SiC. In order to maintain a decreased growth rate even at elevated temperatures (e.g. >1500° C.), a sufficient amount of Si vapor density must be maintained on the SiC surface. Currently, thin and homogeneous graphene layers have been prepared by high temperature annealing of the SiC crystals either in an inductively heated graphite enclosure placed inside a high vacuum furnace or in an inert argon atmosphere. The use of a Si containing environment such as disilane (Si₂H₆) was also found to yield improved graphene morphology with relatively large domain sizes.

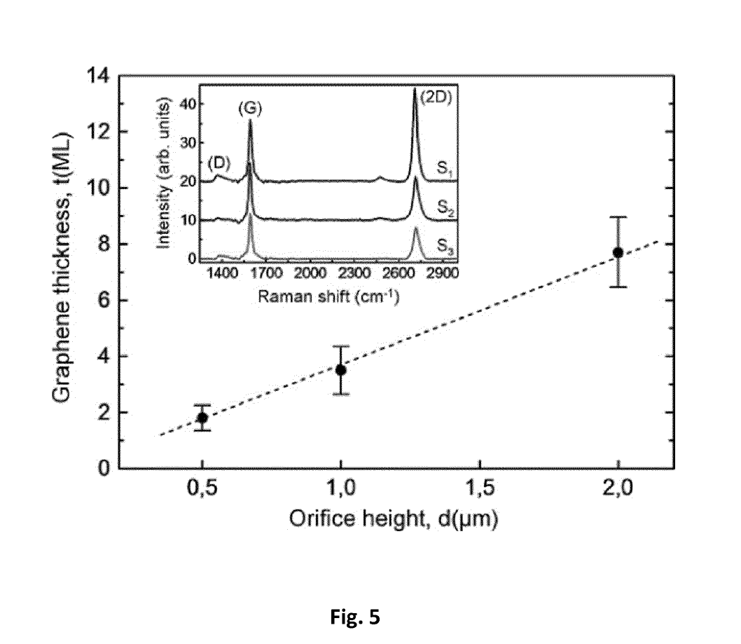

The inventors have previously shown that the confinement of sublimated Si atoms at the interface between a cap/SiC sample stack significantly reduces the graphene growth rate on the C-face of SiC down to an easily controllable range even in ultra-high vacuum (UHV) environment. Upon the above finding, the inventors have also noted that growth rate of graphene has direct relation with the orifice height (d) of the cap/SiC stack. In this instance, the inventors have systematically studied the effect of the degree of Si confinement on the thickness and morphology of epitaxial graphene prepared in UHV conditions, as well as the effect of the said orifice height on growth rate of graphene, where each of those experiments were carried out in “individual cavities” with different orifice heights (see FIG. 4). During the high temperature annealing process (˜1500° C.), the Si atoms evaporated from each capped region of the sample surface were trapped inside the corresponding cavity on top. The cavities between the cap and the sample surface create small volumes of Si vapor density varying with the amount of confinement in each cavity. The presence of Si vapor pressure acting on each capped region retard the sublimated Si atoms to escape freely into vacuum environment. The local confinement of Si vapor in these small volumes promotes the constituent Si atoms to condense back onto the sample surface and thus leads to such a low graphene growth rate that is dependent only on the cavity's orifice height. In this experiment the annealing temperature and the growth duration were inherently the same for all three growth surfaces. Accordingly, it was found out that the graphene layer formed on Sample 1 (S1) was less than S2 which was also less than that of S3. Therefore, it is concluded that the graphene thickness is essentially correlated only with the orifice height (d) as demonstrated in FIG. 5 based on Raman measurements.

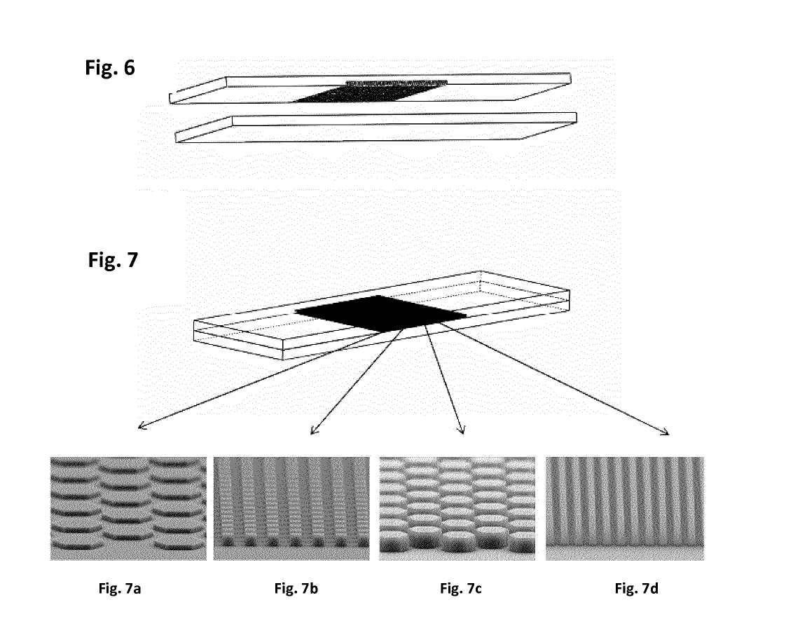

Starting from this basic idea based on capping and growth in a Si confined cavity with adjustment of orifice heights, the inventors have surprisingly found out that the novel material of the present invention having a modulated and integral surface can be obtained by modifying the capping substrate (FIG. 6) such that it has a corresponding modulated surface preferably as an array of protrusions as shown in FIG. 7. The cross-sectional shape of the protrusions may be selected from the group of triangular, quadrangle, hexagonal, and circular shapes or a combination thereof. In more detail the modulated surface with protrusions serve as a negative complementary to the grid structure of graphene sheet where capping structures with protrusions of different shapes can be involved as exemplified in FIGS. 7a, 7b, 7c and 7d.

The inventors have unexpectedly noted that the height modulation caused by the protrusions on the cap can be transferred to the grown graphene sheets even if the cap and the graphene surface on SiC substrate would have no physical contact in the growing process. Without being bound by a theory, the reason is thought to be local increase/drop of the partial pressure and concentration of Si depending on the orifice heights that change with the surface modulation of the capping structure. This is very surprising because normally the pressure in the overall cavity between the SiC base substrate and capping is expected to be constant.

Therefore, there is provided an inventive and straightforward method for producing graphene sheets with surface modulation, preferably with a grid structure comprising the steps as identified below.

A capping structure with modulated surface having varying thickness is provided. In preferred embodiments, a capping wafer as illustrated in FIGS. 6 and 7 which has a surface modulated height profile, or topographically modulated surface is provided. As may be appreciated by those skilled in the art, the protrusions may have different shapes as is the case for the ridges of graphene, where the said protrusions have a suitable arrangement in the form of arrays forming a template for the grid structure of the graphene sheet material according to the present invention. In a preferred embodiment, the cap is a SiC substrate which is the same material as the opposing SiC primary substrate that grows graphene. Forming of protrusions on the cap can be performed with any conventional method such as lithographical methods, chemical etching, plasma etching, ion etching or a combination thereof. The cap as defined above can be used as is or can be annealed before the actual growth to graphitize its surface. The cap can also be chosen from another material which is compatible with the annealing process to follow such as graphite of carbon. SiC, however is particularly preferred as it readily forms a graphite layer on its surface and contributes partial pressure of Si in the stack cavity. Graphite surface advantageously prevents sticking of the cap to the SiC substrate particularly at high temperatures.

The novel method of the present invention comprises placing of the cap as identified above on top of the primary surface which is actually the SiC substrate. As mentioned above, the capping structure is preferably made of SiC just as the primary SiC substrate and is placed on top of said substrate to form a “laterally modulated gap” between two surfaces. This means that capping and the substrate do not have a physical contact therebetween and the orifice height profile along the horizontal direction therein is not constant because of the modulating surface of said capping.

The primary substrate-cap assembly is then annealed to high temperatures such as 1400-2000° C., more preferably 1500-1600° C., and most preferably to about 1500° C. During the high temperature annealing, silicon atoms are sublimated from the capped surfaces and are confined inside the modulated cavity between the two substrates. Confined silicon vapor maintains a relative partial pressure at the sample surface which is also modulated by the cavity height formed by the height modulation of the cap. Graphene growth rate follows the cavity height modulation. After growth is finalized the graphene is formed on the primary surface which has a lateral thickness modulation transferred from the lateral height modulation of the cap.

The method of the present invention allows growing in ultra-high vacuum conditions as well under lower vacuum or in the presence of nonreactive gasses such as argon. The pressure in the vacuum medium can be as low as 10⁻¹⁰ mbar. In a preferred embodiment, the method of the present invention is carried out in an ultra-high vacuum medium (UHV) at a pressure of10⁻¹⁰ to 10⁻⁶ mbar, more particularly of 10⁻¹⁰ to 10⁻⁸ mbar.

The method as described above, can be carried out until the desired thickness of graphene is obtained in the stack. As mentioned previously, the growth rate of graphene can be stimulated by means of changing the orifice height (d) in a preferred location. In a preferred embodiment, the procedure according to the present invention is carried out to obtain a “monolayer” graphene with local ridges forming a grid structure. According to a further embodiment, the method of the invention is adapted to form a bilayer or trilayer graphene with a grid structure.

### Example

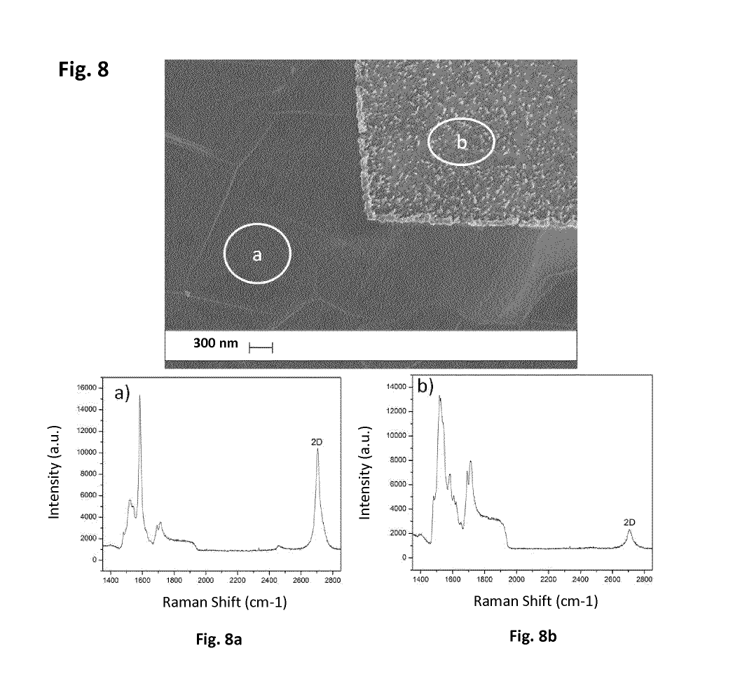

Epitaxial graphene was grown on the carbon-reach surface of SiC (000-1) substrate in ultra-high vacuum (UHV) conditions. Capping structure was also a SiC substrate. A 250 μm thick, on-axis and n-type (the doping concentration of approximately 10¹⁸/cm³) 4H-SiC wafers with atomically flat surfaces (from NovaSiC) were used in the experiments. The wafers were diced into 3 mm wide and 10 mm long rectangular substrates and cleaned chemically. E-beam lithography, wet and dry etching processes were performed on the cap samples in order to obtain lateral height modulation with arrays of hexagonal protrusions as shown in FIG. 7a. The native oxide layers on the samples were removed in diluted HF solution prior to loading into the UHV chamber which has a base pressure of 1×10⁻¹⁰ mbar. The cap substrate was annealed in UHV by direct current heating during which the temperature is measured and controlled with 1° C. resolution individually. Cap-Sample was degassed overnight at around 600° C. and the remaining surface oxide was removed thermally by annealing the samples for about 8 min at 1150° C. before the growing procedure. Cap samples were annealed in UHV for 4 min. at 1320° C. This annealing step removes any trace of surface oxide and possible contamination and also creates a clean and passivized surface layer on the capping substrate. Then the cap was annealed for 5 min. at 1500° C. This carbonization step on the cap sample allows better sticking with original sample. When the cap sample placed on the primary sample, the cavities on the capping substrate provides a well-defined separation between its surface and the primary substrate surface as illustrated FIG. 6. Following the thermal cleaning cycle mentioned above, the sample-cap stack was annealed at 1500° C. for 5 min. in UHV for the graphene growth. Maximum chamber pressure was measured to be 2×10⁻⁸ mbar during the growth stage. In this method, Si atoms thermally decomposed from the sample surface during high temperature annealing of the SiC_{cap}/SiCₛₐₘₚₗₑ stack, were separately trapped inside the cavities at the sample/cap interface. High depth regions provide less Si confinement which leads to growth of thick graphene layer on the other hand, other regions which are almost in contact with the original sample provides high Si confinement eventually allows to growth of thin graphene layers. The special design capping technique provided high quality and uniform thickness modulation on the sample as confirmed by Raman spectroscopy measurements given in FIGS. 8a and 8b. The local ridging area (b) is integrally formed with the graphene layer (a) as seen in FIG. 8, where the said ridging areas (b) have substantially hexagonal shape constituting a network (grid structure) over the entire surface of the graphene sheet.

1. A graphene sheet comprising regularly or irregularly patterned and thickness modulated structure on graphene surface wherein the ridging areas are integrally formed with the graphene sheet and are themselves made of graphene.

2. A graphene sheet according to claim 1 comprising an array of ridges constituting a grid structure on graphene surface for better electrical conductivity wherein the ridging areas are integrally formed with the graphene sheet and are themselves made of graphene.

3. The graphene sheet according to claim 2 comprising by a monolayer graphene sheet with a mono or multi layered grid structure.

4. The graphene sheet according to claim 2 comprising by a bilayer or trilayer graphene sheet with a mono or multi layered grid structure.

5. The graphene sheet according to claim 2 wherein the geometric shapes of the ridging areas are selected from the group of triangular, quadrangle, hexagonal, and circular shapes or a combination thereof.

6. An electronic device comprising the graphene sheet according to claim 1.

7. An electronic device according to claim 6 which is an electrode or a transistor.

8. A display comprising the graphene sheet according to claim 1.

9. The display according to claim 6 which is an OLED.

10. A method for producing a thickness modulated graphene sheet comprising the steps of:
providing a silicon carbide primary substrate,
providing a capping substrate having a modulated surface,
annealing of the capping substrate,
positioning said capping substrate on a top surface of the primary substrate and providing a spacing therebetween to form a cavity with a modulated gap,
heating the substrates to a temperature sufficient to sublimate silicon from the primary substrate and to form a graphene layer thereon, and
proceeding with the sublimation step until a thickness modulated graphene structure is obtained.

11. A method according to claim 10 comprising the steps of:
providing a silicon carbide primary substrate,
providing a capping substrate having a modulated surface, said material having an array of protrusions,
annealing of the capping substrate,
positioning said capping substrate on a top surface of the primary substrate and providing a spacing therebetween to form a cavity with a modulated gap,
heating the substrates to a temperature sufficient to sublimate silicon from the primary substrate and to form a graphene layer thereon, and
proceeding with the sublimation step until a graphene sheet comprising areas of an array of ridges constituting a grid structure with improved electrical conductivity on graphene surface is obtained.

12. The method according to claim 10 wherein the capping substrate is silicon carbide.

13. The method according to claim 10 wherein the method further comprises annealing the capping substrate before the sublimation procedure.

14. The method according to claim 10 wherein the heating is carried out at an annealing temperature ranging from 1400° C. to 2000° C.

15. The method according to claim 14 wherein heating is carried out at an annealing temperature ranging from 1500° C. to 1600° C.

16. The method according to claim 10 wherein the method is carried out under vacuum at a pressure lower than 10⁻⁴ mbar.

17. The method according to claim 11 wherein the graphene sheet is monolayer with a mono or multi layered grid structure.

18. The method according to claim 11 wherein the graphene sheet is bilayer or trilayer with a mono or multi layered grid structure.

19. The method according to claim 11 wherein cross-sectional shape of the protrusions is selected from the group of triangular, quadrangle, hexagonal, and circular shapes or a combination thereof.

20. The method according to claim 10 wherein graphene sheet is formed on the C-terminated face of the primary substrate.
